(19) United States
(12) Patent Application Publication
(10) Pub. No.: US 2005/0208900 A1
(43) Pub. Date: Sep. 22, 2005

(54) Co-existing BluetoothTM and wireless local area networks

(76) Inventor: Ulun Karacaoglu, San Diego, CA (US)

Correspondence Address: INTEL CORPORATION, P.O. BOX 5326, SANTA CLARA, CA, 95056-5326, US

(21) Appl. No.: 10/802,201

(22) Filed: Mar. 16, 2004

(51) Int. Cl. H04B 1/44; H04B 1/02; H03C 7/02; H04B 7/02; H04B 1/04

(52) U.S. Cl. 455/78; 455/575.7; 455/127.4; 455/133; 455/277.1

(57) ABSTRACT

Two antennas provide signals and a diversity switch selects the antenna providing the highest signal strength for a WLAN module. A Bluetooth™ module is routed or switched to receive a signal from the unused antenna or the antenna not in use by WLAN module.

The proliferation of mobile computing devices including laptops, Personal Digital Assistants (PDAs) and wearable computing devices has created a demand for Wireless Local Area Networks (WLANs). A key challenge in the design of a WLAN device is adapting to a hostile radio environment that includes noise, time-varying channels, and abundant electromagnetic interference. The emergence of several radio technologies, such as Bluetooth™ and IEEE 802.11 that operate in the 2.4 GHz frequency band may lead to signal interference that results in performance degradation when devices are closely located. What is needed is a system that provides a better way to accommodate both WLAN and Bluetooth™ communications.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 illustrates a diversity switch providing an interface between dual antennas and RF modules in accordance with the present invention; and

FIG. 2 is a diagram that highlights features of the diversity switch illustrated in FIG. 1.

It will be appreciated that for simplicity and clarity of illustration, elements illustrated in the figures have not necessarily been drawn to scale. For example, the dimensions of some of the elements may be exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

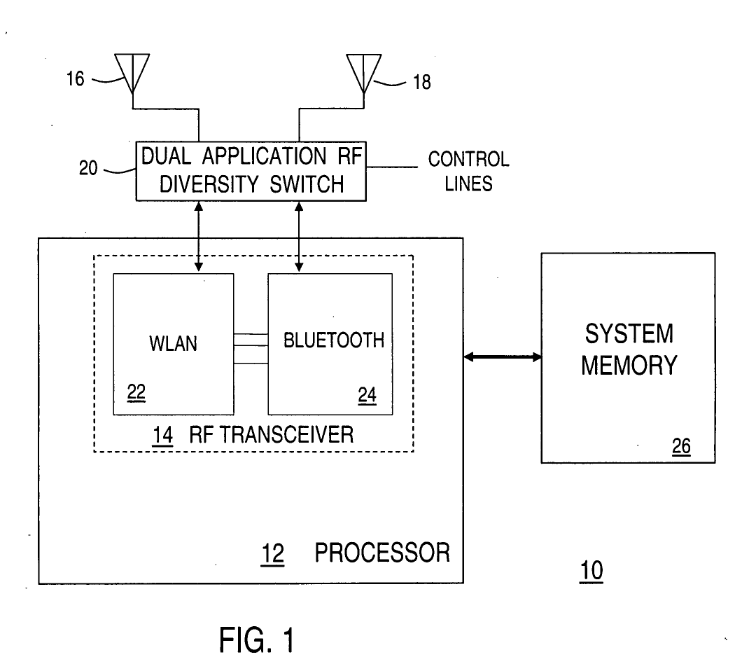

FIG. 1 illustrates a device 10 that includes a transceiver 14 that either receives or transmits a modulated signal from two or more antennas. In the receive mode, the modulated signals received by antennas 16 and 18 are passed through a diversity switch 20, with control lines selecting the appropriate modulated signals as Bluetooth™ or Wireless Local Area Network (WLAN) signals. WLAN signals are directed to a WLAN module 22 to be frequency down-converted, filtered and converted to a baseband digital signal. On the other hand, Bluetooth™ signals are directed to a Bluetooth module 24 to be frequency down-converted, filtered, and converted to a baseband digital signal. After the analog signals are converted to digital data in RF transceiver 14, the data may be stored in memory device 26. In one embodiment, memory device 26 may be a NOR or NAND Flash, a battery backed-up DRAM, or a polymer memory such as ferroelectric memory, a plastic memory or a resistive change polymer memory.

In one embodiment, the analog front end transceiver includes WLAN module 22 and Bluetooth module 24 as separate modules that interface with diversity switch 20. In another embodiment, WLAN module 22 and Bluetooth module 24 may be integrated together and connect to diversity switch 20. In yet another embodiment, WLAN module 22, Bluetooth module 24 and diversity switch 20 may be integrated as a stand-alone Radio Frequency (RF) analog circuit or embedded with processor 12 as a mixed-mode integrated circuit. Note that the selection of WLAN modules and Bluetooth modules and their combination with switches for integration should not be a limitation of the claimed subject matter.

Embodiments of the present invention for device 10 may be used in a variety of applications, with the claimed subject matter incorporated into microcontrollers, general-purpose microprocessors, Digital Signal Processors (DSPs), Reduced Instruction-Set Computing (RISC), Complex Instruction-Set Computing (CISC), among other electronic components. In particular, the present invention may be used in communicators and Personal Digital Assistants (PDAs), medical or biotech equipment, automotive safety and protective equipment and automotive infotainment products. However, it should be understood that the scope of the present invention is not limited to these examples.

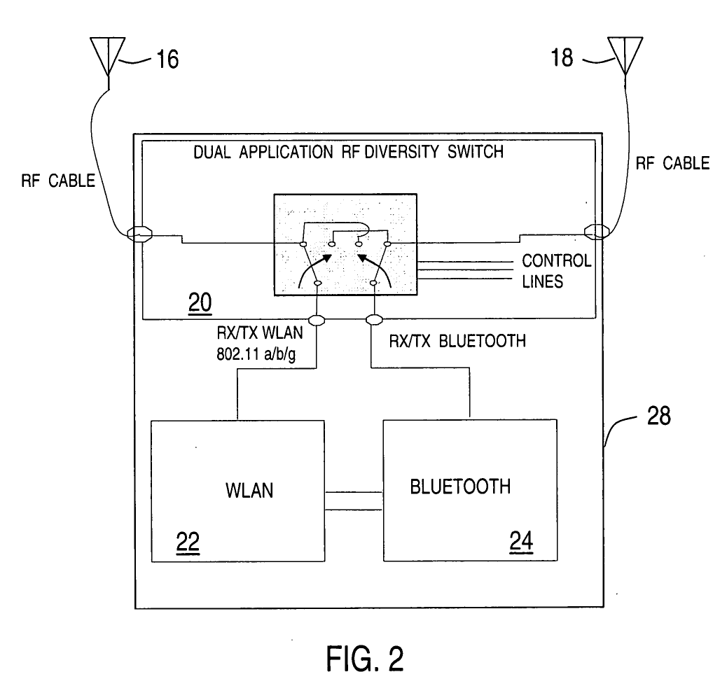

FIG. 2 further illustrates features of device 10 where the WLAN module 22 and the Bluetooth module 24 are interfaced through the dual application RF diversity switch 20 to accommodate routing signals to/from the desired antenna. In contrast to prior art systems that include a board having a Bluetooth module with its own antennas and a WLAN module with its own antennas, the illustrated embodiment includes WLAN module 22 and Bluetooth module 24 implemented on the same board and sharing antennas. Thus, in accordance with the present invention, the antennas used to provide WLAN signaling may also be used to provide Bluetooth signaling. This feature helps reduce board space and allows removal of the co-existence cabling requirements for Bluetooth and WLAN.

The embodiment shown in FIG. 2 may be used with a mini-Peripheral Component Interconnect (mPCI) assembly 28 having a module capable of communicating with one or any combination of 802.11a, 802.11b and 802.11g WLAN networks and another module for communicating with Bluetooth networks. 802.11 refers to specifications developed by the IEEE for wireless LAN technology and specifies an over-the-air interface between a wireless client and a base station of between two wireless clients.

Diversity switch 20 may be used to resolve WLAN and Bluetooth communications on the same mPCI board without adding a new antenna and RF cabling to the platform. WLAN module 22 may be considered the master module that uses antennas 16 and 18 as diversity antennas, with each antenna used one at a time. Therefore, at least one of the antennas is a redundant antenna which may be used for Bluetooth module 24 (the slave module).

Diversity switch 20 provides selection of one of the diversity antenna to be used by WLAN module 22, with the unused antenna assigned to the Bluetooth™ system. Thus, Bluetooth module 24 basically uses the existing antennas and RF cables that are currently available for WLAN and enables Bluetooth signaling to be included in device 10. In accordance with the present invention, both Bluetooth and WLAN systems may be implemented on the same mPCI board without making antenna and RF cable additions to the mobile platform.

In operation and by way of example, antennas 16 and 18 may be selected to provide WLAN module 22 with multiple copies of the signal or signal redundancies as transmitted by another device. Diversity techniques are one line of defense against multipath fading in modern wireless systems. WLAN module 22 may receive a signal having a low signal strength from antenna 16 for instance, which prompts diversity switch 20 to switch antennas and allow WLAN module 22 to receive signals from antenna 18 instead. In this example where WLAN module 22 switches to receive signals from antenna 18, Bluetooth module 24 is automatically routed or switched to receive signals from the unused antenna, i.e., antenna 16 in this example. Thus, Bluetooth module 24 is assigned the antenna not in use by WLAN module 22.

By now it should be apparent that the complexity of a wireless device communicating in different networks may be mitigated using features of the present invention. A diversity switch connected to both a WLAN module and to a Bluetooth module can account for received signal strengths and allow the wireless communications device to communicate in both networks.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A wireless device, comprising:
first and second antennas;
first and second transceivers; and
a switch to select first and second antennas to couple to the first transceiver to provide diversity, wherein the switch further selects the first antenna or the second antenna not coupled to the first transceiver to couple to the second transceiver.

2. The wireless device of claim 1 wherein the first transceiver is a Wireless Local Area Network (WLAN) transceiver.

3. The wireless device of claim 1 wherein the second transceiver is a Bluetooth™ transceiver.

4. The wireless device of claim 3 wherein the Bluetooth™ transceiver uses the first and second antennas that are for WLAN signaling to enable Bluetooth™ signaling in the wireless device.

5. The wireless device of claim 1 wherein the first and second transceivers are separate modules assembled with the switch on a board and cable connected to the first and second antennas.

6. A transceiver system comprising:
first and second antennas;
first and second transceivers; and
a switch controlled to provide a first signal received from the first antenna or a second signal received from the second antenna to the first transceiver where control is based on signal strength of the first and second signals, wherein the switch is further controlled to provide the first or second signal that is not provided to the first transceiver to the second transceiver.

7. The transceiver system of claim 6 wherein the first transceiver is a Wireless Local Area Network (WLAN) transceiver.

8. The transceiver system of claim 6 wherein the second transceiver is a Bluetooth™ transceiver.

9. The transceiver system of claim 6 further including a processor where the first and second transceivers are embedded with the processor as a mixed-mode integrated circuit.

10. The transceiver system of claim 9 further including Flash memory coupled to the processor.

11. A method, comprising:
selecting a first antenna or a second antenna to provide a signal to a WLAN transceiver; and
using the antenna not selected to provide the signal to the WLAN transceiver for providing a signal for a Bluetooth™ transceiver.

12. The method of claim 11 wherein selecting a first antenna or a second antenna further includes determining signal strength of the signal provided by the first and second antennas.

13. The method of claim 12 wherein selecting a first antenna or a second antenna further includes using a switch controlled to select the signal provided to the WLAN transceiver.

14. The method of claim 11 further including using the first and second antennas that are for WLAN signaling to enable Bluetooth™ signaling in a wireless device.

15. The method of claim 14 further including using a flash memory to store data received by the wireless device.
